(19) United States
(12) Patent Application Publication
(10) Pub. No.: US 2026/0043868 A1
(43) Pub. Date: Feb. 12, 2026

(54) A METHOD FOR DETERMINING THE SWELLING STATE OF A BATTERY

(71) Applicant: SIMPLO TECHNOLOGY CO., LTD., Hsinchu County (TW)

(72) Inventors: Kuo-Liang TENG, Hsinchu County (TW); Yi-Ren GUO, Hsinchu County (TW)

(21) Appl. No.: 19/171,766

(22) Filed: Apr. 7, 2025

(30) Foreign Application Priority Data
Aug. 7, 2024 (TW) 113129485

(51) Int. Cl. G01R 31/392; G01R 31/367; G01R 31/385

(52) U.S. Cl. CPC G01R 31/392; G01R 31/367; G01R 31/385

(57) ABSTRACT

A method for determining the swelling state of a battery is provided, comprising the following steps: collecting data of multiple charging voltage differences and cumulative operating units of the battery; obtaining the variation data of the current charging voltage difference based on the charging voltage differences and cumulative operating units; acquiring the known relational data between variation data of charging voltage differences and battery swelling states, and determining the swelling state of battery based on the relational data and the variation data of the current charging voltage difference. Accordingly, it is possible to predict whether the battery is at risk of swelling. The method for determining the swelling state of a battery provided by the embodiments of the present invention allows a more convenient prediction of the swelling state of a battery based on the variation data of the charging voltage difference.

### CROSS-REFERENCE TO RELATED APPLICATION

This non-provisional application claims priority under 35 U.S.C. § 119(a) on Patent Application No. 113129485 filed in Taiwan on Aug. 7, 2024 entitled “A Method of Determining of Cell Swelling”, the entire contents of which are hereby incorporated by reference.

### BACKGROUND OF THE INVENTION

### Field of the Invention

The present invention relates to a method for determining the swelling state of a battery, and more particularly to a method for determining the swelling state of the battery using the variation data of the voltage differences.

### Description of the Prior Art

As electricity becomes more and more integrated into daily life, lithium-ion battery packs are widely used in consumer electronics, home appliances and even automobiles. Regardless of its application, battery aging and swelling are critical issues. Battery aging is an inevitable process. At present, it only slows down the battery capacity and usage time, which does not lead to a significant risk. On the other hand, although battery swelling does not occur in each battery, it represents irreversible damage to the battery. If the casing of a swelling battery is damaged by external force, it may catch fire or explode. Even without an external force, continued use of a swelling battery will accelerate aging and increase the risk.

Currently, battery swelling is measured by mechanics or mechanical methods such as pressure or strain gauges. It is accurate when the battery is at rest, but it can be prone to errors under small external forces. This method requires additional sensors to be set up for measurement, and only detects battery swelling after it has occurred, and then advises the user to replace the battery. According to the prior art, battery swelling lacks a quantitative description and is only categorized into two states: swelling and not swelling.

Chinese Patent Publication No. CN113484781A discloses a method for detecting battery swelling, comprising: obtaining the internal resistance growth rate of the battery and the first pressure difference; determining the first swelling rate of the battery based on the internal resistance growth rate, and determining the second swelling rate based on the first pressure difference; and determining the swelling rate of the battery based on the first and second swelling rates. The first pressure difference is the difference between the maximum voltage value and the minimum voltage value during the battery charging process. According to this technology, the internal resistance growth rate is primarily used as a method for detecting battery swelling.

### SUMMARY OF THE INVENTION

An objective of one embodiment of the present invention is to provide a method for determining the swelling state of a battery, which is capable of assessing the swelling state of the battery. An objective of another embodiment of the present invention is to provide a method for determining the swelling state of a battery, which can more conveniently predict the swelling state of the battery based on the variation data of charging voltage differences.

According to an embodiment of the present invention, a method for determining the swelling state of a battery is provided, comprising the following steps. Collecting data of multiple charging voltage differences and cumulative operating unit values of a battery. Obtaining the variation data of a current charging voltage difference based on the charging voltage differences and the cumulative operating unit values. Acquiring known relational data between variation data of charging voltage differences and battery swelling states, and determining the swelling state of the battery based on the relational data and the variation data of the current charging voltage difference.

In one embodiment, the charging voltage differences of the battery are multiple fully charged voltage differences of the battery.

In one embodiment, the variation data of the current charging voltage difference is a growth slope Sᵢ of a current fully charged voltage difference. The step of collecting data on multiple charging voltage differences and the cumulative operating unit values of a battery includes: collecting data of the fully charged voltage differences ΔVₛₜₒₚ and cumulative operating unit values DT of the battery within a predetermined temperature range. The step of obtaining the variation data of a current charging voltage difference based on the charging voltage differences and the cumulative operating unit values includes: calculating the growth slope Sᵢ of the current fully charged voltage difference based on the data of the fully charged voltage differences ΔVₛₜₒₚ and the cumulative operating unit values DT.

In one embodiment, the cumulative operating unit D_{T} is cycle count, usage time, or accumulated capacity.

In one embodiment, the step of calculating the growth slope Sᵢ of the current fully charged voltage difference further comprises: performing regression analysis on the data of the fully charged voltage differences ΔVₛₜₒₚ and cumulative operating unit values DT of the battery to determine the growth slope Sᵢ of the current fully charged voltage difference.

In one embodiment, the known relational data is the relationship data between the growth slopes and the battery swelling degrees.

In one embodiment, the relational data between the growth slope and the battery swelling degree is a correspondence table containing data of multiple values of the growth slopes and the battery swelling degrees. Furthermore, the step of determining the swelling state of the battery further includes: determining the swelling degree of the battery based on the correspondence table and the growth slope Sᵢ of the current fully charged voltage difference.

In one embodiment, the relational data between the growth slopes and the battery swelling degrees includes a first threshold value. Furthermore, the step of determining the swelling state of the battery further includes: determining that the battery is in a swelling state when the growth slope Sᵢ of the current fully charged voltage difference is greater than the first threshold value.

In one embodiment, the relational data between the growth slopes and the battery swelling degrees further includes a second threshold value. Furthermore, the step of determining the swelling state of the battery further includes: determining that the battery is in a pre-swelling state when the growth slope Sᵢ of the current fully charged voltage difference is greater than the second threshold value.

In one embodiment, the relational data between the growth slopes and the battery swelling degrees includes a calculated threshold value determined based on a constant K_{S} of a material of the battery. Furthermore, the step of determining the swelling state of the battery further includes: determining that the battery is in a swelling state when the growth slope Sᵢ of the current fully charged voltage difference is greater than the calculated threshold value.

In one embodiment, the step of collecting data of the fully charged voltage differences ΔVₛₜₒₚ and cumulative operating unit values D_{T} of the battery within a predetermined temperature range further comprises the following steps: charging the battery to a fully charged state, and then let the battery rest for an equilibrium time T_{B}; obtaining the voltages Vₗₐₛₜ of the fully charged state of the battery within the predetermined temperature range; obtaining the equilibrium voltage VB after resting for the equilibrium time T_{B}; calculating the fully charged voltage differences ΔVₛₜₒₚ of the battery based on the voltages Vₗₐₛₜ of the fully charged state of the battery and the equilibrium voltage V_{B} within the predetermined temperature range.

According to one embodiment of the present invention, the swelling state of a battery is judged by analyzing the variation data of the charging voltage difference and the cumulative operating unit values D_{T}. In another embodiment, it is preferred to use the variation data of multiple fully charged voltage differences for analysis and assessment, so that the current swelling state of the battery can be predicted.

### BRIEF DESCRIPTION OF THE DRAWINGS

The disclosure is illustrated by embodiments, depicted by accompanying drawings, and described below. The accompanying drawings are not drawn to scale, depending on standards accepted in related art. For the sake of clear illustration, the dimensions of parts and components shown in the accompanying drawings may be increased or decreased as desired.

FIG. 1 shows a curve graph of the growth slope of the fully charged voltage difference and total firmware execution time of three batteries with different swelling degrees, as well as a bar chart of their swelling rates and total firmware execution time.

FIG. 2A shows a curve graph corresponding to curve C1_slope in FIG. 1, illustrating the fully charged voltage difference of battery VC1 against the total firmware execution time.

FIG. 2B shows a curve graph corresponding to curve C3_slope in FIG. 1, illustrating the fully charged voltage difference of battery VC3 against the total firmware execution time.

FIG. 3 shows a functional block diagram of an electrical product according to one embodiment of the present invention.

FIG. 4A shows a curve graph of voltage versus time during battery charging.

FIG. 4B shows a flowchart of the measurement steps for the fully charged voltage difference.

FIG. 5A shows a flowchart of the method for determining the swelling state of a battery.

FIG. 5B shows a curve graph of the fully charged voltage differences of the battery against the total firmware execution times of the battery.

FIG. 5C shows another curve graph of the fully charged voltage differences against the total firmware execution times of the battery.

### DETAILED DESCRIPTION OF THE EMBODIMENTS

The present invention addresses the shortcomings of the prior art by adopting a new algorithm, thus finding an effective strategy to solve the above problems. By analyzing the variation data of charging voltage differences and the current data related to battery usage time correlation (such as time or cycle count), it can be determined whether the battery is at risk of swelling, thereby allowing for preventive measures to be taken to significantly reduce the occurrence of battery swelling. The so-called determination can involve detection, prediction, or calculation, among others. Unlike the existing methods that use voltage difference, the method of the present invention uses the charging voltage differences and also the variation data of the voltage differences (such as rate of change, growth slope, or ratio) to assess the battery swelling state. Furthermore, in one embodiment, the method can quantitatively classify the battery swelling state, and can provide a description of the current condition of the battery and a risk assessment of potential future swelling that may lead to battery failure. The so-called “charging voltage difference” refers to the voltage difference between the voltage of the battery at the moment before or during the execution of a charging procedure and the voltage of the battery after a predetermined time following the above charging procedure.

According to an embodiment of the present invention, it can be applied to rechargeable lithium-ion batteries. By measuring the variation data of charging voltage differences, it is possible to determine whether the battery may swell in the future and to assess the current swelling condition of the battery. Preferably, in the determining method of one embodiment, the analysis and determination use the variation data of multiple fully charged voltage differences. The so-called “fully charged voltage difference” refers to the voltage difference between the voltage of the battery at the moment before the execution of a full charging procedure and the voltage of the battery after a predetermined time following the above full charging procedure. In one embodiment, the multiple voltage differences obtained are further subjected to linear regression analysis, and then the slope of the regression line is compared to predict whether there is a risk of swelling in the subsequent use of the battery. More specifically, the relationship between the slope of the regression line obtained from the voltage difference analysis and the swelling is obtained to predict the current swelling state of the battery. The detailed explanation is as follows.

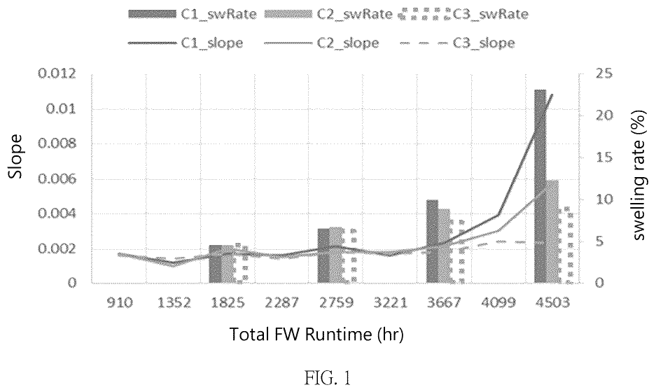

FIG. 1 shows a curve graph of the growth slope of the fully charged voltage difference and total firmware execution time, as well as a bar chart of their swelling rates and total firmware execution time, for three batteries with different swelling degrees. FIG. 1 shows the curves of the growth slopes, from C1_slope to C3_slope, for multiple batteries and the bars of the swelling rates, from C1_swRate to C3_swRate, for these batteries. From FIG. 1, it can be seen that the battery VC1 corresponding to curve C1_slope has the highest degree of swelling. It can also be seen that after a total firmware execution time of 4099 hours, the growth slope in battery VC1's curve C1_slope rises very rapidly. In contrast, the battery VC3 corresponding to curve C3_slope has the minimal degree of swelling. It can also be seen that at a total firmware execution time of 4099 hours, the growth slope in battery VC3's curve C3_slope remains very gentle. The swelling degree of battery VC2, corresponding to curve C2_slope, lies between that of batteries VC1 and VC3. It can also be seen that at a total firmware execution time of 4099 hours, the growth slope in battery VC2's curve C2_slope is also between the slopes of curve C1_slope and curve C3_slope. Additionally, it can be seen that at a total firmware execution time of approximately 3667 hours, curves C1_slope to C3_slope begin to gradually diverge, and by this time, curves C1_slope to C3_slope are no longer intertwined and can be distinguished from each other.

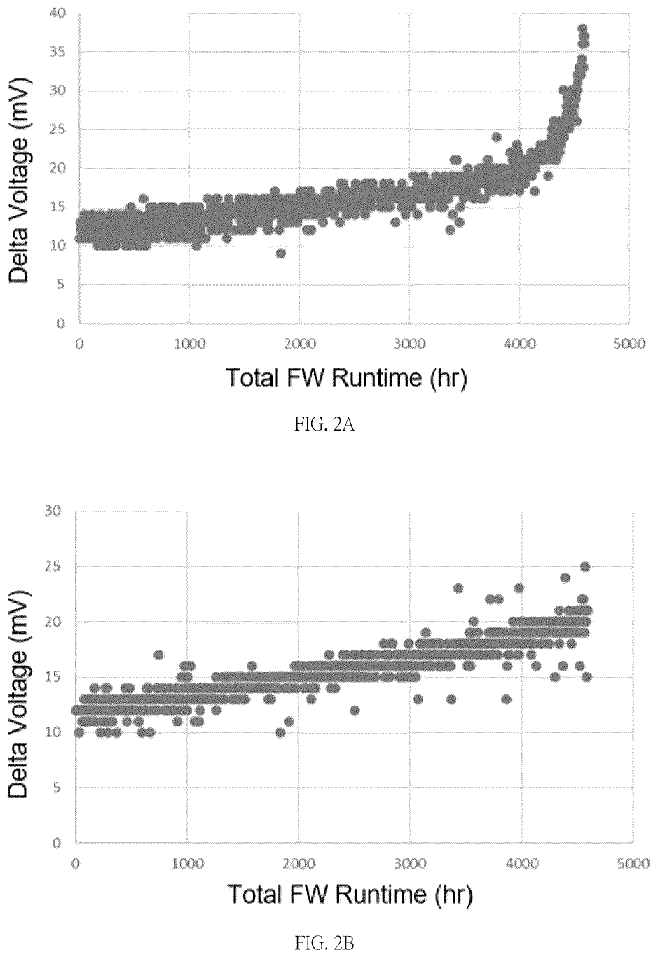

FIG. 2A shows a curve graph corresponding to curve C1_slope in FIG. 1, illustrating the fully charged voltage difference of battery VC1 against the total firmware execution time. FIG. 2B shows a curve graph corresponding to curve C3_slope in FIG. 1, illustrating the fully charged voltage difference of battery VC3 against the total firmware execution time. From FIG. 2A, it can be seen that at around a total firmware execution time of 4100 hours, curve C1_slope starts to rise rapidly. From FIGS. 1 and 2A-2B, it can be seen that using the growth slope of the voltage difference (variation data or ratio) can predict the future battery swelling state more quickly and is suitable for assessing the battery swelling condition.

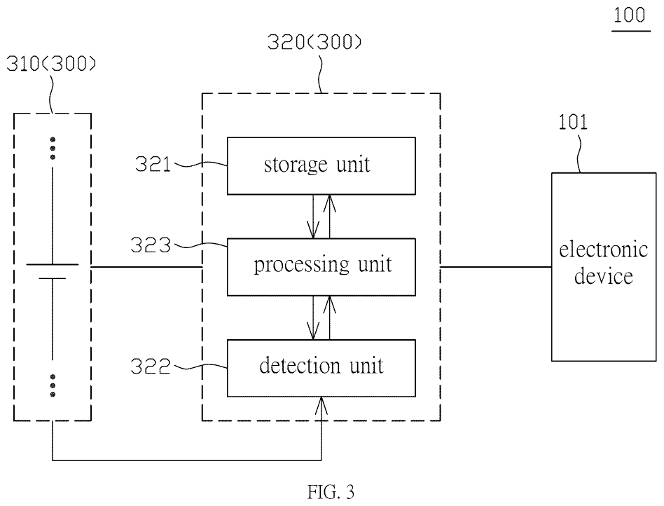

FIG. 3 shows a functional block diagram of an electrical product according to one embodiment of the present invention. The electronic product 100 includes a battery module 300 and an electronic device 101. The method for determining the swelling state of a battery according to an embodiment of the present invention can be applied to the battery module 300. As shown in FIG. 3, the battery module 300 is connected to the electronic device 101 and includes a battery 310 and a control system 320. The control system 320 can execute the above method for determining the swelling state of the battery and includes a storage unit 321, a detection unit 322, and a processing unit 323. The storage unit 321 can be, for example, a memory, used to store various operational data, such as lookup tables, functions, parameters, or critical values. The detection unit 322 is connected to the battery 310 to obtain battery information such as voltage, current, temperature, or cumulative operating unit values D_{T} from battery 310. The processing unit 323 acquires the data needed to determine the swelling state of the battery from the storage unit 321 and the detection unit 322 to estimate and determine the swelling state of the battery 310. In one embodiment, the processing unit 323 can also be used to obtain the cumulative operating unit values D_{T}. Furthermore, a person skilled in the art can determine the structure of the battery 310 and control system 320 based on the disclosure of the present invention, the characteristics of circuit components used in implementing the present invention, and/or the effects desired to be achieved during the implementation of the present invention. Additionally, a person skilled in the art may implement equivalent changes based on the above disclosures. The electronic product 100 can be a 3C product such as a laptop, mobile phone, or camera, or a product like automotive electronics.

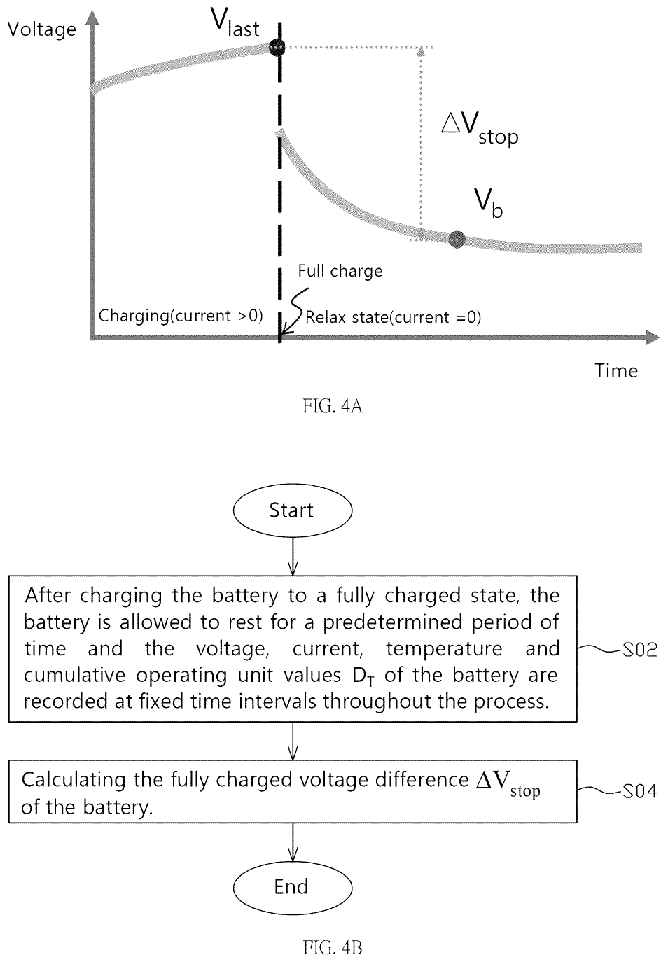

FIG. 4A shows a curve graph of voltage versus time during battery charging. FIG. 4B shows a flowchart of the measurement steps for the fully charged voltage difference. Please refer to FIGS. 4A to 4B; the measurement steps of the fully charged voltage difference of the battery include the following steps.

Step S02: After charging the battery to a fully charged state, the battery is allowed to rest for a predetermined period of time and the voltage, current, temperature and cumulative operating unit values D_{T} of the battery are recorded at fixed time intervals throughout the process. The cumulative operating unit values D_{T} may be units having a correlation to the battery usage time, for example, data such as cycle counts, usage time, and accumulated capacity. In one embodiment, it is preferable that the predetermined time is greater than or equal to the equilibrium time T_{B} for measuring the voltage difference. Once the battery is fully charged and has undergone the equilibrium time T_{B}, the chemicals in the positive and negative electrodes of the battery reach an equilibrium state, during which the battery's voltage remains stable.

Step S04: Calculating the fully charged voltage difference ΔVₛₜₒₚ of the battery. In one embodiment, it is preferable to obtain the voltage Vₗₐₛₜ of the battery at the moment before or during the execution of the full charging program measured in step S02. The battery is then allowed to rest for the equilibrium time T_{B} after reaching the fully charged state in order to obtain the equilibrium voltage V_{B}. In step S04, the fully charged voltage difference ΔVₛₜₒₚ of the battery is calculated using the following formula (1).

$${ΔV}_{stop} = {V}_{last} - {V}_{B} \qquad ( 1 )$$

It should be noted that although the fully charged voltage difference ΔVₛₜₒₚ of the battery is used in this invention to explain the embodiments, it can also be modified to use the voltage difference ΔVₛₜₒₚ before and after charging as a method of determining the swelling state of the battery. The voltage difference in this embodiment, which is obtained based on the equilibrium time T_{B}, can also be obtained based on a predetermined time set independently.

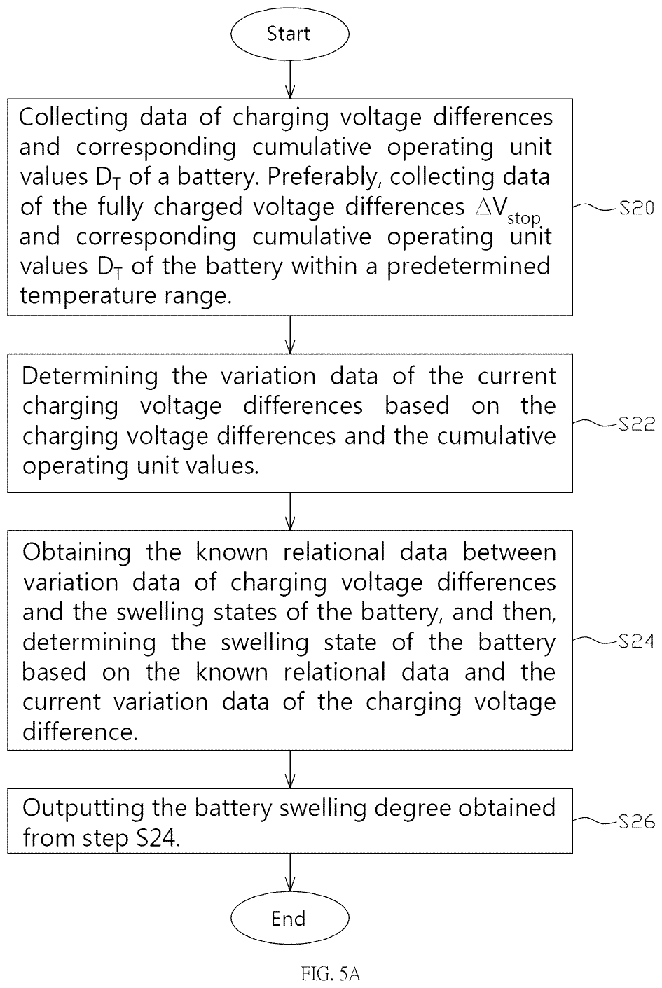

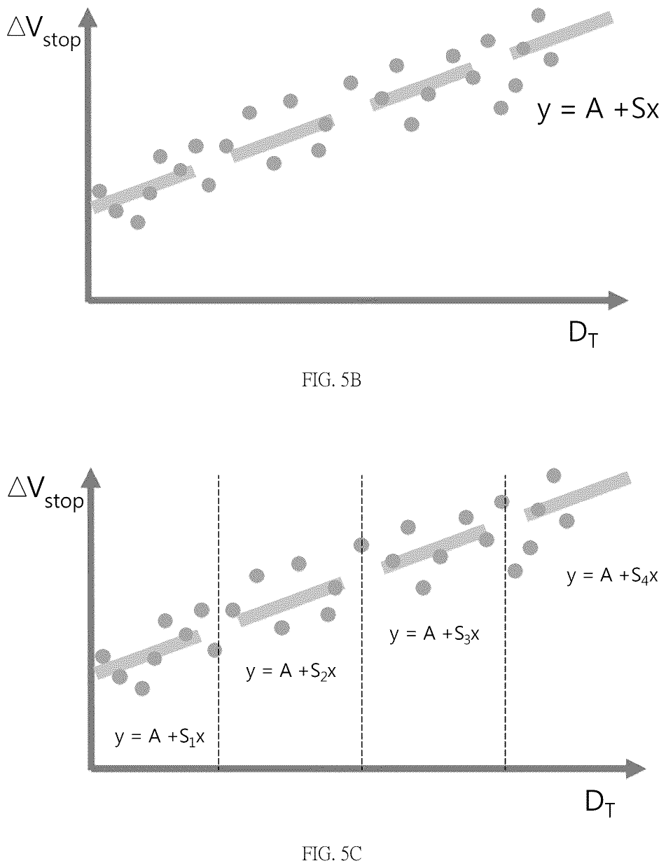

FIG. 5A shows a flowchart of the method for determining the swelling state of a battery. As shown in FIG. 5A, the method for determining the swelling state of a battery according to one embodiment of the present invention includes the following steps.

Step S20: Collecting data of charging voltage differences and corresponding cumulative operating unit values D_{T} of a battery. Preferably, collecting data of the fully charged voltage differences ΔVₛₜₒₚ and corresponding cumulative operating unit values D_{T} of the battery within a predetermined temperature range.

More specifically, the fully charged voltage differences ΔVₛₜₒₚ of a battery at different temperature ranges and their corresponding cumulative operating unit values D_{T} are obtained. The fully charged voltage differences ΔVₛₜₒₚ of the battery within the same temperature range is classified. The fully charged voltage differences ΔVₛₜₒₚ within the predetermined temperature range is used as the data for subsequent regression analysis. Furthermore, regression analysis is also carried out after a certain amount of data has been collected within a specific section of the cumulative operating unit values D_{T}. For example, if the cumulative operating unit values D_{T} refer to the number of battery cycles, the data obtained from the first 100 cycles (initial quantity T_{Ini}) can be used as the initial calculation reference. Then, each N cycles is taken as the interval T_{C} of the cumulative operating unit values D_{T}, and the slope of the regression line is calculated for each interval T_{C}. In the present invention, there is no limit to the size of N, and it can be set according to the characteristics of the product, for example, it can be set to 100 cycles.

FIG. 5B shows a curve graph of the fully charged voltage differences of the battery against the total firmware execution times of the battery. Step S22: Determining the variation data of the current charging voltage differences based on the charging voltage differences and the cumulative operating unit values. See FIG. 5B, preferably calculate the slope of the fully charged voltage differences ΔVₛₜₒₚ of the battery. Preferably, a linear regression is performed on the data of the fully charged voltage differences ΔVₛₜₒₚ and the corresponding cumulative operating unit values D_{T} of the battery to obtain a regression line corresponding to the fully charged voltage differences ΔVₛₜₒₚ and the corresponding cumulative operating unit values D_{T} of the battery, and then the current growth slope Sᵢ of this regression line is obtained.

It should be noted that there is no specific size relation between the initial quantity T_{Ini} and the interval T_{C} of the cumulative operating unit values D_{T}. When the initial quantity T_{Ini} is less than the interval T_{C}, the initial growth slope S_{Ini} of the fully charged voltage difference ΔVₛₜₒₚ of the battery is recorded at T_{Ini}, then the first growth slope Sᵢ of the fully charged voltage difference ΔVₛₜₒₚ is calculated at the interval T_{C}, and the growth slope Sᵢ is calculated at each subsequent interval T_{C}. In one embodiment, it is also possible to obtain the data at each interval T_{C} by means of a moving interval (or varying and different intervals). When the initial quantity T_{Ini} is greater than or equal to the interval T_{C}, the initial growth slope S_{Ini} of the fully charged voltage difference ΔVₛₜₒₚ of the battery is recorded at T_{Ini}, then the first growth slope Sᵢ of the fully charged voltage difference ΔVₛₜₒₚ is calculated at T_{Ini}+T_{C} of the cumulative operating unit values D_{T}, and the growth slope Sᵢ is calculated at each subsequent interval T_{C}. In one embodiment, it is also possible to obtain the data at each interval T_{C} by means of a moving interval (or varying and different intervals). FIG. 5C shows another curve graph of the fully charged voltage differences of the battery against the total firmware execution times of the battery. As shown in FIG. 5C, the growth slopes S1-4 are derived from data of different intervals of cumulative operating unit values D_{T}, which helps to more accurately obtain current information. Unlike the embodiment of FIG. 5C, the embodiment of FIG. 5B calculates the growth slope Sᵢ from all, at least most, or at least part of the data prior to the current cumulative operating unit values D_{T}, which provides more comprehensive information about the battery's historical process. A person skilled in the art can suitably choose the calculation method of FIG. 5B or FIG. 50 according to product needs and, of course, can also appropriately modify the method for obtaining the growth slope as described above.

Step S24: Obtaining the known relational data between variation data of charging voltage differences and the swelling states of the battery, and then, determining the swelling state of the battery based on the known relational data and the current variation data of the charging voltage difference. Preferably, obtain known relational data between the growth slopes of the fully charged voltage differences ΔVₛₜₒₚ and the swelling degrees of the battery, and determine the battery's swelling degree based on the relational data and the current growth slope Sᵢ.

Step S26: Outputting the battery swelling degree obtained from step S24. Preferably, output it to an electrical product 100 to be displayed on the display of the electrical product 100, or through other output devices, such as a speaker that outputs sound.

In one embodiment of step S24, the relational data between the growth slopes and the battery swelling degrees includes a correspondence table containing data of multiple swelling degrees and growth slopes. The swelling degree can be represented numerically or described textually. More specifically, the relational data between the growth slopes and the battery swelling degrees can be a correspondence table containing numerical values of multiple swelling degrees and the corresponding growth slopes. Alternatively, the relational data can be a correspondence table containing textual descriptions of multiple swelling degrees and the corresponding ranges of growth slopes. In another embodiment of step S24, the relational data between the growth slopes and the battery swelling degrees can be the data of the growth slope when the battery is in a swelling state. Preferably, the relational data includes a first threshold, which corresponds to the threshold at which the battery is already in a swelling state. In one embodiment, this relational data includes a second threshold, which corresponds to another threshold at which the battery is in a pre-swelling (or an early stage of swelling). In one embodiment, the relational data between the growth slopes and the battery swelling degrees includes an estimated threshold determined according to a constant K_{S} of a material of the battery. More specifically, a constant K_{S} can be obtained based on the battery material, and then an estimated threshold of the growth slope when the battery is in a swelling state can be determined, based on the constant K_{S} and the initial growth slope S_{Ini} of the fully charged voltage difference ΔVₛₜₒₚ of the battery.

According to one embodiment of step S24, the relational data between the growth slopes and the battery swelling degrees can be obtained experimentally, and may be a correspondence table that contains numerical values of multiple swelling degrees and the corresponding ranges of growth slopes. A detailed explanation is given below using Example 1.

### Example 1

The number of battery cycles (battery cycle count) is used as the cumulative operating unit value D_{T}. The initial quantity T_{Ini} is set to 200 cycles, and the interval T_{C} for calculating the slope of the regression line is 200 cycles, with the battery temperature range being 15° C. to 45° C. According to Example 1, the swelling degrees of the battery are divided into 6 subclasses using the quantified values “0, 1, 2, 3, 4, 5”, where the value 0 indicates the battery is in a completely non-swelling state, and the value 5 indicates the battery is in a swelling state. To achieve the above function, the memory of the battery module in Example 1 stores the following Table 1.

TABLE 1

| | Swelling Degree | | | | | |
|---|---|---|---|---|---|---|
| | 0 | 1 | 2 | 3 | 4 | 5 |
| Slope Sᵢ | <0.007 | 0.007~0.011 | 0.011~0.015 | 0.015~0.018 | 0.018~0.020 | >0.020 |

Table 1 is a correspondence table containing numerical values of multiple swelling degrees and the corresponding growth slope ranges at temperatures of 15° C. to 45° C. The swelling degrees in Table 1 are obtained by categorizing the swelling rates acquired from experiments. In one embodiment, the swelling rate is determined using the original thickness T_{Pori} of the battery, the current thickness T_{Pi}, and the thickness T_{PF} in the swelling state. In this embodiment, the original thickness of the battery is used as the original thickness T_{Pori}, and the thickness of the battery measured just before the swelling state is used as the thickness T_{PF} in the swelling state, then the equation for calculating the swelling degree is as follows:

$$Swelling Degree = ( {T}_{Pi} - {T}_{Pori} ) / ( {T}_{PF} - {T}_{Pori} ) \qquad ( 2 )$$

Furthermore, the swelling degree is categorized based on the swelling rates obtained from experiments and the corresponding growth slopes Sᵢ. It should be noted that using the battery's thickness is one of the various methods of calculating swelling degree; any characteristic related to battery swelling can be used to calculate the swelling degree. The thickness T_{PF} in the swelling state of the battery can be the corresponding thickness (or characteristic value) measured just before the swelling state, or the corresponding thickness (or characteristic value) during the swelling, with the former being a more conservative evaluation method.

In step S22, the initial growth slope S_{Ini} is determined to be 0.0076 at the initial quantity T_{Ini}.

At the 1st interval T_{C}, the 1st growth slope S₁ is determined to be 0.0068. Since the 1st growth slope S₁<0.007, the battery's swelling degree is judged to be 0.

At the 2nd interval T_{C}, the 2nd growth slope S₂ is determined to be 0.0078, and the battery's swelling degree is judged to be 1.

At the 3rd interval T_{C}, the 3rd growth slope S₃ is determined to be 0.0077, and the battery's swelling degree is judged to be 1.

At the 4th interval T_{C}, the 4th growth slope S₄ is determined to be 0.0089, and the battery's swelling degree is judged to be 1.

At the 5th interval T_{C}, the 5th growth slope S₅ is determined to be 0.0078, and the battery's swelling degree is judged to be 1.

At the 6th interval T_{C}, the 6th growth slope S₆ is determined to be 0.0098, and the battery's swelling degree is judged to be 1.

At the 7th interval T_{C}, the 7th growth slope S₇ is determined to be 0.0103, and the battery's swelling degree is judged to be 1.

At the 8th interval T_{C}, the 8th growth slope S₈ is determined to be 0.0174, and the battery's swelling degree is judged to be 3.

At the 9th interval T_{C}, the 9th growth slope S₉ is determined to be 0.0254, and the battery's swelling degree is judged to be 5.

When the 9th growth slope S₉ is measured and found to be S₉>0.020, the battery is already in a swelling state. In this situation, even if there is no obvious swelling visible on the exterior of the battery, and even if the battery is left unused, swelling is likely to occur in the short term. Therefore, it is not recommended to continue using this battery.

The relational data between the growth slopes and the battery swelling degrees can also be obtained experimentally, and may be a correspondence table that contains textual descriptions of multiple swelling degrees and the corresponding ranges of growth slopes. A detailed explanation is given below using Example 2.

### Example 2

Example 2 is similar to Example 1, so the same parameters, elements, or steps use the same symbols and omit their corresponding descriptions. The following only illustrates at least one difference between the two examples. In Example 2, the swelling degree is not represented numerically but instead is expressed using textual descriptions. However, the growth slope fields, similar to Example 1, are represented as a range of intervals. To achieve the above function, the memory of the battery module in Example 2 stores the following Table 2.

TABLE 2

| | | | Slight | Noticeable |
|---|---|---|---|---|
| Swelling Degree | No Swelling | Pre-swelling | Swelling | Swelling |
| Slope Sᵢ | <0.010 | 0.010~0.015 | 0.015~0.020 | >0.020 |

Table 2 is a correspondence table containing textual descriptions of multiple swelling degrees and the corresponding growth slope ranges at temperatures of 15° C. to 45° C.

Please refer to the previous paragraphs and Table 2. It can be seen that before or at the time of measuring the 6th growth slope S₆, the battery shows no signs of swelling and there is no risk of battery swelling. However, the values are already approaching the “pre-swelling state” range. When the 7th growth slope S7 is measured to be 0.0103, it is seen that the battery is in the pre-swelling state. When the 8th growth slope S₈ is measured to be 0.0174, it can be known that the battery has already started to experience slight swelling. Even though the battery may not appear to have swelling problems from its appearance, the battery has begun to exhibit swelling behavior. If it continues working, it will undergo significant swelling and deformation in the near future. When the 9th growth slope S₉ is measured to be 0.0254, exceeding the threshold of 0.020, that is 0.0254>0.020, it indicates that the battery is in a noticeable swelling state, that is the swelling state according to Example 2. Under such circumstances, even if the battery does not appear to have swelling problems based on its appearance and even if the battery is left unused, significant swelling is likely to occur soon. Therefore, continued use of this battery is not recommended.

Integrating Examples 1 and 2, practically, the slopes can be divided into multiple subclasses based on demand, with each subclass assigned a corresponding swelling degree. For example, the slopes could be quantified as numerical values, as in Example 1: “0, 1, 2, 3, 4, 5”, which are divided into 6 subclasses; or as general descriptive text, as in Example 2: “No swelling, pre-swelling, slight swelling, noticeable swelling”, which are divided into 4 subclasses. Here, “pre-swelling state” refers to a high tendency toward swelling without any swelling occurrence yet. “Slight Swelling” indicates that swelling has started but is not significant. According to this embodiment, the primary advantage is to effectively detect when a battery is in the “pre-swelling state.” In one embodiment, the relational data between the growth slopes and the battery swelling degrees may include a first threshold. The initial growth slope S_{Ini} of the fully charged voltage difference ΔVₛₜₒₚ of the battery is taken as the initial state. The growth slope S_{Final} of the fully charged voltage difference ΔVₛₜₒₚ, representing the battery is in the swelling state, is taken as the first threshold. The current growth slope Sᵢ is calculated to predict the corresponding swelling degree of the battery. If Sᵢ is greater than or equal to the first threshold (S_{Final}), the battery is considered to be in a swelling state; if Sᵢ is less than the first threshold (S_{Final}), the battery is not yet considered to be in a swelling state. However, the closer Sᵢ is to the first threshold (S_{Final}), the greater the likelihood that the battery will enter a swelling state. In one embodiment, the relational data between the growth slopes and the battery swelling degrees may further include a second threshold. The growth slope S_{early} of the fully charged voltage difference ΔVₛₜₒₚ, which represents that the battery is in the pre-swelling state, is taken as the second threshold. The current growth slope Sᵢ is calculated to predict the corresponding swelling degree of the battery. If Sᵢ is greater than or equal to the second threshold (Searly), the battery is considered to be in the pre-swelling state. In one embodiment, the relational data may include both the first and second threshold, wherein the second threshold is less than the first threshold.

### Example 3

Example 3 is similar to Example 2, so the same parameters, elements, or steps use the same symbols and omit their corresponding descriptions. The following only illustrates at least one difference between the two examples. In Example 3, the relational data does not use the form of a correspondence table. Instead, the known growth slope S_{Final} of the battery swelling is stored directly in the memory of the battery module as 0.018. It should be noted that in other variations, the growth slope S_{Final} of the battery swelling can also be formatted for storage in a table such as the following Table 3.

TABLE 3

| Swelling Degree | Swelling State |
|---|---|
| Slope S_{Final} | >0.018 |

Please refer to the previous paragraphs. It can be seen that before or at the time of measuring the 8th growth slope S₈, the battery shows no signs of swelling and there is no risk of battery swelling. However, the values are approaching the growth slope S_{Final} of the battery swelling, indicating a higher probability of swelling during subsequent use. To delay the onset of swelling, the charging conditions can be adjusted to reduce the risk of battery swelling. When the 9th growth slope S₉>S_{Final} is measured, it can be known that the battery is in a swelling state. Under such circumstances, even if the battery does not appear to have swelling problems based on its appearance and even if the battery is left unused, significant swelling is likely to occur soon. Therefore, continued use of this battery is not recommended.

In another embodiment of step S24, the growth slope when the battery is in a swelling state can be obtained experimentally, or data such as the constant K_{S} of the battery material corresponding to this growth slope can also be obtained experimentally. More specifically, in another embodiment, a constant K_{S} obtained based on the battery material, and the initial battery full charge voltage difference ΔVₛₜₒₚ are both used in calculation of the growth slope S_{Final} in the battery swelling state. The method of calculating the estimated threshold is given by the following formula.

$${S}_{Final} = {S}_{Ini} \times {K}_{S} \qquad ( 3 )$$

When the current growth slope Sᵢ approaches the estimated growth slope S_{Final}, it indicates that continued use of the battery carries a high risk of swelling. Conversely, the farther and smaller the Sᵢ is from the estimated growth slope S_{Final}, the lower the likelihood of swelling. If Sᵢ is greater than or equal to S_{Final}, the battery is considered to be in a swelling state. In other variations, the initial growth slope S_{Ini} of the battery's fully charged voltage difference ΔVₛₜₒₚ can serve as a reference. When the calculated current growth slope Sᵢ increases rapidly, there is a higher risk of battery swelling. In other words, the faster the growth slope Sᵢ increases, the higher the risk of battery swelling. A detailed explanation is given below using Example 4.

### Example 4

Example 4 is similar to Example 3, so the same parameters, elements, or steps use the same symbols and omit their corresponding descriptions. The following only illustrates at least one difference between the two examples. In Example 4, the memory of the battery module stores a known growth slope S_{Final} for battery swelling corresponding to a battery material with its constant K_{S} being 2.5 and the calculation formula as S_{Final}=S_{Ini}×K_{S}. It should be noted that in other variations, the growth slope S_{Final} for battery swelling, with its constant K_{S} being 2.5 and its calculation formula S_{Final}=S_{Ini}×K_{S}, can also be formatted for storage in a table such as the following Table 4.

TABLE 4

| Swelling Degree | Swelling State |
|---|---|
| Constant K_{S} | 2.5 |
| Slope S_{Final} | >S_{Ini} × K_{S} |

Please refer to the previous paragraphs. The growth slope S_{Final} for the battery swelling can be calculated using the formula S_{Final}=S_{Ini}×K_{S}, which gives S_{Final}=0.0076×2.5=0.019. It can be seen that before or at the time of measuring the 8th growth slope S₈, the battery shows no signs of swelling. When the 9th growth slope S₉>S_{Final} is measured, it can be known that the battery is in a swelling state.

As described above, in Example 3, a predetermined threshold is provided. If the growth slope exceeds this threshold, the battery is considered to be in the swelling state. On the other hand, In Example 4, the initial growth slope S_{Ini} is measured for each manufacturing batch of batteries, and then multiplied by a predetermined constant K_{S} to estimate the threshold for that batch of batteries. The K_{S} value can be obtained through experimentation and may vary depending on the characteristics of the battery materials in different manufacturing batches. Compared to Example 3, Example 4 can address problems caused by manufacturing variations in the batteries and allows for the estimation of different thresholds for each manufacturing batch, thereby improving the accuracy of determining battery swelling.

According to one embodiment of the present invention, the swelling state of a battery is assessed by analyzing the data of the variation data of the charging voltage difference and the cumulative operating unit values D_{T}. In another embodiment, it is preferred to use the variation data of multiple fully charged voltage differences for analysis and evaluation to predict the current swelling state of the battery.

What is claimed is:

1. A method for determining the swelling state of a battery, comprising:
collecting data of multiple charging voltage differences and cumulative operating unit values of the battery;
obtaining the variation data of a current charging voltage difference based on the charging voltage differences and the cumulative operating unit values;
acquiring known relational data between variation data of charging voltage differences and battery swelling states, and determining the swelling state of the battery based on the relational data and the variation data of the current charging voltage difference.

2. The method of claim 1, wherein the charging voltage differences of the battery are multiple fully charged voltage differences of the battery.

3. The method of claim 2, wherein
the variation data of the current charging voltage difference is a growth slope Sᵢ of a current fully charged voltage difference;
the step of collecting data on multiple charging voltage differences and cumulative operating unit values of a battery includes: collecting data of the fully charged voltage differences ΔVₛₜₒₚ and the cumulative operating unit values D_{T} of the battery within a predetermined temperature range;
the step of obtaining the variation data of a current charging voltage difference based on the charging voltage differences and the cumulative operating unit values includes: calculating the growth slope Sᵢ of the current fully charged voltage difference based on the data of the fully charged voltage differences ΔVₛₜₒₚ and the cumulative operating unit values D_{T}.

4. The method of claim 3, wherein
the cumulative operating unit is cycle count, usage time, or accumulated capacity.

5. The method of claim 3, wherein the step of calculating the growth slope Sᵢ of the current fully charged voltage difference further comprises:
performing regression analysis on the data of the fully charged voltage differences ΔVₛₜₒₚ and cumulative operating unit values D_{T} of the battery to determine the growth slope Sᵢ of the current fully charged voltage difference.

6. The method of claim 3, wherein the known relational data is the relationship data between the growth slopes and the battery swelling degrees.

7. The method of claim 6, wherein
the relational data between the growth slope and the battery swelling degrees is a correspondence table containing data of multiple values of the growth slopes and the battery swelling degrees;
the step of determining the swelling state of the battery further includes: determining the swelling state of the battery based on the correspondence table and the growth slope Sᵢ of the current fully charged voltage difference.

8. The method of claim 6, wherein
the relational data between the growth slopes and the battery swelling degrees includes a first threshold;
the step of determining the swelling state of the battery further includes: determining that the battery is in the swelling state when the growth slope Sᵢ of the current fully charged voltage difference is greater than the first threshold.

9. The method of claim 6, wherein
the relationship data between the growth slopes and the battery swelling degrees includes a second threshold;
the step of determining the swelling state of the battery further includes: determining that the battery is in a pre-swelling state when the growth slope Sᵢ of the current fully charged voltage difference is greater than the second threshold.

10. The method of claim 1, wherein
the relationship data between the growth slopes and the battery swelling degrees includes a calculated threshold determined based on a constant K_{S} of a material of the battery;
the step of determining the swelling state of the battery further includes: determining that the battery is in the swelling state when the growth slope Sᵢ of the current fully charged voltage difference is greater than the calculated threshold.

11. The method of claim 3, wherein the step of collecting data of the fully charged voltage differences ΔVₛₜₒₚ and the cumulative operating unit values D_{T} of the battery within a predetermined temperature range further comprises the following steps:
charging the battery to a fully charged state, and then let the battery rest for an equilibrium time T_{B};
obtaining the voltages Vₗₐₛₜ of the fully charged state of the battery within the predetermined temperature range;
obtaining the equilibrium voltage V_{B} after resting for the equilibrium time T_{B}; and
calculating the fully charged voltage differences ΔVₛₜₒₚ of the battery based on the voltages Vₗₐₛₜ of the fully charged state of the battery and the equilibrium voltage V_{B} within the predetermined temperature range.
